(19) United States
(12) Patent Application Publication
(10) Pub. No.: US 2019/0390061 A1
(43) Pub. Date: Dec. 26, 2019

(54) MULTI-LAYERED STRUCTURE AND SUBSTRATE

(71) Applicants: ITEQ Corporation, Xinpu Township (TW); Industrial Technology Research Institute, Hsinchu (TW)

(72) Inventors: Chen-Hsi CHENG, Xinpu Township (TW); Ming-Hung HUANG, Xinpu Township (TW)

(73) Assignees: ITEQ Corporation, Xinpu Township (TW); Industrial Technology Research Institute, Hsinchu (TW)

(21) Appl. No.: 16/015,544

(22) Filed: Jun. 22, 2018

(51) Int. Cl. C09D 4/06; B32B 15/08; B32B 15/14; B32B 27/20; C09D 171/12; H05K 1/03; H05K 1/02; H05K 3/00; H05K 3/02; H05K 3/46

(52) U.S. Cl. CPC C09D 4/06; C08K 2003/385; B32B 15/14; B32B 27/20; C09D 171/12; H05K 1/0366; H05K 1/0204; H05K 1/0373; H05K 3/0011; H05K 3/022; H05K 3/4626; B32B 2262/101; B32B 2255/26; B32B 2255/02; B32B 2457/08; B32B 15/08

(57) ABSTRACT

A multi-layered structure is provided, which includes a carrier and a resin coating on the carrier, wherein the resin coating is formed by magnetically aligning and drying a resin composition. The resin composition includes 1 part by weight of (a) crosslinkable monomer with a biphenyl group, 1.0 to 20.0 parts by weight of (b) polyphenylene oxide, 0.1 to 10.0 parts by weight of (c) hardener, and 0.1 to 80.0 parts by weight of (d) magnetic filler. (d) Magnetic filler is boron nitride, aluminum nitride, silicon nitride, silicon carbide, aluminum oxide, carbon nitride, octahedral carbon, or a combination thereof, with a surface modified by iron-containing oxide. (d) Magnetic filler is sheet-shaped or needle-shaped.

### TECHNICAL FIELD

The technical field relates to a multi-layered structure, and in particular it relates to a resin coating (free of glass fiber cloth) of the multi-layered structure.

### BACKGROUND

Circuit boards and IC substrates produced for the optoelectronics and semiconductor industries are trending toward high-speed, high-density, intensive, and high integration because of the rise of the “Cloud”, the “Internet”, the “Internet of things”, enhancements of 4G and 5G communication technologies, and improvements in display technologies. The required properties of the circuit boards and the IC substrates of the future are not only low dielectric constant and high insulation, but also low dielectric loss and high thermal conductivity. For example, the copper clad laminate in a circuit board is concisely represented as copper foil/dielectric layer/copper foil, and the middle dielectric layer is usually composed of resin, glass fiber cloth, or insulation paper with low thermal conductivity. Therefore, the copper clad laminate has poor thermal conductivity. In general, a large amount of thermally conductive powder is often added to the dielectric layer to increase the thermal conductivity of the dielectric layer. However, the resin between the thermally conductive powder is not thermally conductive, causing the thermally conductive effect of the thermally conductive powder dispersed in the resin to be limited.

A novel thermally conductive resin collocated with the thermally conductive powder is called for to overcome the above issue and increase the thermal conductivity of the dielectric layer between the copper foils.

### SUMMARY

One embodiment of the disclosure provides a multi-layered structure, including a carrier and a resin coating on the carrier. The resin coating is formed by magnetically aligning and drying a resin composition. The resin composition includes 1.0 part by weight of (a) crosslinkable monomer with a biphenyl group, 1.0 to 20.0 parts by weight of (b) polyphenylene oxide, 0.1 to 10.0 parts by weight of (c) hardener, and 0.1 to 80.0 parts by weight of (d) magnetic filler. (d) Magnetic filler is boron nitride, aluminum nitride, silicon nitride, silicon carbide, aluminum oxide, carbon nitride, octahedral carbon, or a combination thereof, with a surface modified by iron-containing oxide, and (d) magnetic filler is sheet-shaped or needle-shaped.

In one embodiment, the resin coating is free of glass fiber cloth.

In one embodiment, (a) crosslinkable monomer with a biphenyl group has terminal alkylene groups, which has a chemical structure of:

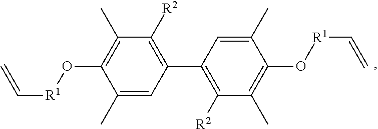

wherein R¹ is —CH₂—, —C(═O)—, or —(CH₂)—(C₆H₄)—; and R² is H or CH₃.

In one embodiment, (b) polyphenylene oxide has terminal alkylene groups, which has a chemical structure of:

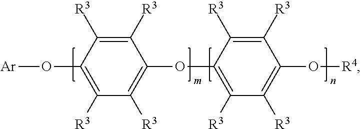

wherein Ar is aromatic group, each of R³ is independently of H, CH₃,

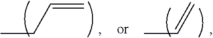

### R⁴ is

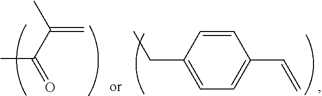

m and n are positive integers, and m+n=6˜300.

In one embodiment, (c) hardener comprises triallyl isocyanurate, trivinyl amine, triallyl cyanurate, or a combination thereof.

In one embodiment, the resin composition includes 0.001 to 0.05 parts by weight of (e) radical initiator.

In one embodiment, (a) crosslinkable monomer with a biphenyl group has terminal epoxy groups, which has a chemical structure of:

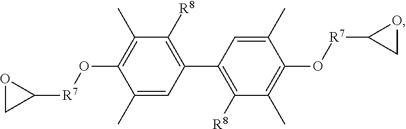

wherein R⁷ is —(CH₂)ₙ—, and n=1˜3, and R⁸ is H or CH₃.

In one embodiment, (b) polyphenylene oxide has terminal hydroxyl groups, which has a chemical structure of:

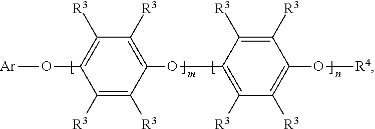

wherein Ar is aromatic group, each of R³ is independently of H, CH₃,

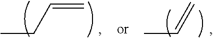

### R⁴ is

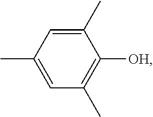

m and n are positive integers, and m+n=6˜300.

In one embodiment, (c) hardener comprises active ester, multi-amine compound, multi-alcohol compound, or a combination thereof.

In one embodiment, the resin composition includes 1.0 to 10.0 parts by weight of (f) compatibilizer, which has a chemical structure of:

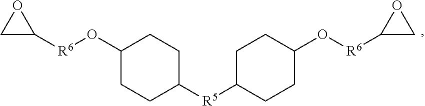

wherein R⁵ is —CH₂— or —C(CH₃)₂—; and R⁶ is —(CH₂)ₙ—, and n=1˜3, wherein (b) polyphenylene oxide has terminal alkylene groups, which has a chemical structure of:

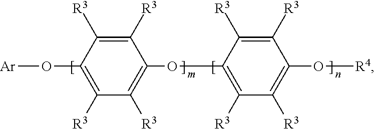

wherein Ar is aromatic group, each of R is independently of H, CH₃,

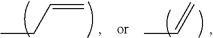

### R is

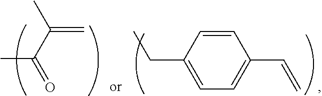

m and n are positive integers, and m+n=6˜300.

In one embodiment, (c) hardener includes (c1) triallyl isocyanurate, trivinyl amine, triallyl cyanurate, or a combination thereof and (c2) active ester, multi-amine compound, multi-alcohol compound, or a combination thereof.

In one embodiment, the resin composition includes 0.001 to 0.05 parts by weight of (e) radical initiator.

In one embodiment, the resin composition includes 0.01% to 10.0% parts by weight of coupling agent.

In one embodiment, the coupling agent is added onto the surface of (d) magnetic filler.

One embodiment of the disclosure provides a substrate, including the two multi-layered structures laminated to each other.

In one embodiment, the substrate has a thickness of 50 μm to 500 μm.

In one embodiment, the substrate includes a prepreg disposed between the two multi-layered structures and laminated with the two multi-layered structures, wherein the prepreg is formed by impregnating a reinforcing material into another resin composition, and then magnetically aligning and drying the other resin composition. The other resin composition includes 1.0 part by weight of (a) crosslinkable monomer with a biphenyl group, 1.0 to 20.0 parts by weight of (b) polyphenylene oxide, 0.1 to 10.0 parts by weight of (c) hardener, and 0.1 to 80.0 parts by weight of (d) magnetic filler.

In one embodiment, the reinforcing material includes glass, ceramic, carbon material, resin, or a combination thereof, and the reinforcing material has the shape of fiber, powder, sheet, texture, or a combination thereof.

### BRIEF DESCRIPTION OF THE DRAWINGS

The disclosure can be more fully understood by reading the subsequent detailed description and examples with references made to the accompanying drawings, wherein:

FIG. 1 shows a multi-layered structure in one embodiment of the disclosure;

FIG. 2 shows a substrate in one embodiment of the disclosure; and

FIG. 3 shows a substrate in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are shown schematically in order to simplify the drawing.

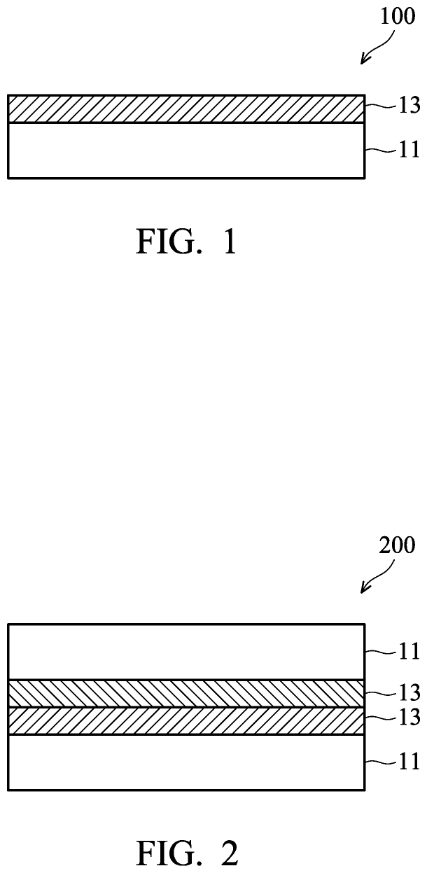

One embodiment of the disclosure provides a multi-layered structure, which can be formed by a resin coated substrate process. As shown in FIG. 1, the multi-layered structure 100 includes a carrier 11 and a resin coating 13 on the carrier 11. In one embodiment, the resin coating 13 can be formed by coating a resin composition onto a carrier. The resin composition is then aligned by a magnetic field, and then dried to form a resin coating 13. In one embodiment, the resin composition and the resin coating 13 therefrom are free of glass fiber cloth. For example, the resin composition can be coated on the carrier 11, and then put into an external magnetic field system of 0.1 Tesla to 10 Tesla, and (d) magnetic filler (will be detailed described as below) is aligned by the magnetic field. The external magnetic field direction is perpendicular to the surface direction of the carrier 11. In one embodiment, the magnetic alignment period is tuned as 0.01 seconds to 1000 seconds. A higher intensity of the external magnetic field needs a shorter magnetic alignment period, and vice versa. However, strength of the external magnetic field that is too high will dramatically increase the equipment cost. Strength of the external magnetic field that is too low will dramatically increase the magnetic alignment period. The magnetically aligned resin composition and the carrier 11 are then put into an oven at 50.0° C. to 500.0° C. for drying the resin composition to form the resin coating 13 (B-stage), thereby obtaining the multi-layered structure 100 with the resin coating 13 on the carrier 11. In one embodiment, the carrier 11 can be copper foil, polymer film (such as polyimide film, polyethylene terephthalate film, or another polymer film), or the like. When the carrier 11 is copper foil, the process of coating the resin composition onto the carrier 11 is the so-called resin coated copper (RCC) process. In one embodiment, the two multi-layered structures 100 can be laminated to each other to form a substrate 200 (copper clad laminate), as shown in FIG. 2. In one embodiment, the lamination process can be performed at a pressure of 5 kg to 50 kg at a pressure of 150° C. to 250° C. for a period of 1 hour to 10 hours. During the lamination process, the one resin coating 13 of the one multi-layered structure 100 directly contacts the other resin coating 13 of the other multi-layered structure 100. In one embodiment, the substrate 200 has a thickness of 50 μm to 500 μm. When the carrier 11 of the multi-layered structure 100 is copper foil, the substrate 200 is the so-called copper laminate clad (CCL).

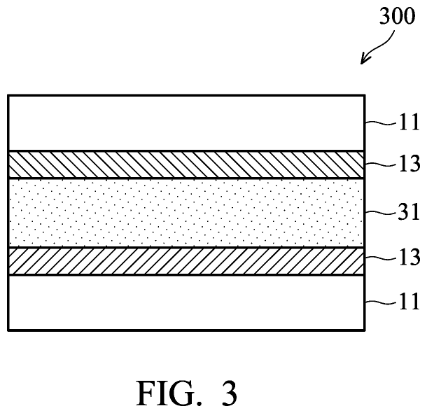

Alternatively, a reinforcing material can be impregnated in another resin composition. The other resin composition is then aligned by a magnetic field, and then dried to form a prepreg 31. The other resin composition (containing the reinforcing material impregnating therein) may have a composition similar to or different from the composition of the resin composition coated on the carrier 11 to form the resin coating 13. In one embodiment, the reinforcing material includes glass, ceramic, carbon material, resin, or a combination thereof, and the reinforcing material has the shape of fiber, powder, sheet, texture, or a combination thereof. For example, the reinforcing material is a glass fiber cloth. In one embodiment, the glass fiber cloth is impregnated in the resin composition (A-stage). The glass fiber cloth impregnated in the resin composition is put into an external magnetic field system of 0.1 Tesla to 10 Tesla, and (d) magnetic filler is aligned by the magnetic field. The external magnetic field direction is perpendicular to the surface direction of the glass fiber cloth. In one embodiment, the magnetic alignment period is tuned as 0.01 seconds to 1000 seconds. A higher intensity of the external magnetic field needs a shorter magnetic alignment period, and vice versa. However, strength of the external magnetic field that is too high will dramatically increase the equipment cost. Strength of the external magnetic field that is too low will dramatically increase the magnetic alignment period. The magnetically aligned glass fiber cloth is then put into an oven at 50.0° C. to 500.0° C. for drying the resin composition, thereby obtaining a prepreg (B-stage). The prepreg 31 formed through the steps of magnetic alignment and drying has properties such as high thermal conductivity, low dielectric constant, low dielectric loss, and the like. In one embodiment, one or more of the prepreg 31 can be disposed between the two multi-layered structures 100 and then laminated to form a substrate 300, as shown in FIG. 3. When the carrier 11 of the multi-layered structure 100 is copper foil, the substrate 300 is the so-called copper laminate clad (CCL). In one embodiment, the lamination process can be performed at a pressure of 5 kg to 50 kg at a pressure of 150° C. to 250° C. for a period of 1 hour to 10 hours. During the lamination process, the one or more prepregs 31 contact the resin coatings 13 of the multi-layered structures 100.

The resin coating 13 of the substrate 200 in FIG. 2 is free of the glass fiber cloth. As such, the resin coating 13 has a higher thermal conductivity, a lower dielectric constant, and a lower dielectric loss than those of the prepreg 31 (containing the reinforcing material such as the glass fiber cloth). On the other hand, the resin coating 13 free of the glass fiber cloth may dramatically reduce the thickness of the substrate 200. If the one or more prepregs are disposed between the carriers and then thermally laminated to form the substrate, the substrate will have a thickness of hundreds of micrometers. However, if the two multi-layered structured 100 are directly laminated to each other to form the substrate 200 as shown in FIG. 2, the substrate 200 may have a thickness of tens to hundreds of micrometers. In addition, the RCC process is beneficial to mass production and continuous process. As described above, the prepreg 31 (containing the reinforcing material such as the glass fiber cloth) can be disposed between the two multi-layered structures 100, and then laminated to form a substrate 300 (see FIG. 3) for modifying the mechanical strength of the substrate 300.

In one embodiment, the resin composition includes (a) crosslinkable monomer with a biphenyl group. (b) polyphenylene oxide, (c) hardener, and (d) magnetic filler. (b) Polyphenylene oxide amount is 1.0 to 20.0 parts by weight on the basis of 1.0 part by weight of (a) crosslinkable monomer with a biphenyl group. A ratio of (b) polyphenylene oxide that is too high may result a cured resin composition having poor thermal conductivity. A ratio of (b) polyphenylene oxide that is too low may result the cure resin composition having poor electrical properties, such as dielectric constant (Dk) and dielectric loss (Df). (c) Hardener amount is 0.1 to 10.0 parts by weight on the basis of 1.0 part by weight of (a) crosslinkable monomer with a biphenyl group. A ratio of (c) hardener that is too high may result in a substrate including the cured resin composition having poor physical properties due to an insufficient crosslinking degree of the cured resin composition. A ratio of (c) hardener that is too low may result in a substrate including the cured resin composition having poor processability due to an insufficient curing of the cured resin composition. (d) Magnetic filler amount is 0.1 to 80.0 parts by weight on the basis of 1.0 part by weight of (a) crosslinkable monomer with a biphenyl group. A ratio of (d) magnetic filler that is too high may reduce the tensile strength of the substrate including the cured resin composition. Furthermore, the substrate is easily burst. A ratio of (d) magnetic filler that is too low may result in the cured resin composition having poor thermal conductivity.

(d) Magnetic tiller is boron nitride, aluminum nitride, silicon nitride, silicon carbide, aluminum oxide, carbon nitride, octahedral carbon, or a combination thereof, with a surface modified by iron-containing oxide, and (d) magnetic filler is sheet-shaped or needle-shaped. In one embodiment, (d) magnetic filler can be prepared as disclosed in Taiwan Patent No. 1588251. Alternatively, 0.01% to 10.0% parts by weight of a coupling agent (on the basis of 1.0 part by weight of (a) crosslinkable monomer with a biphenyl group) is added to the resin composition to increase the compatibility between (d) magnetic filler and the other organic materials in the resin composition. Too much coupling agent may reduce physical properties of the substrate including the cured resin composition. In one embodiment, the coupling agent can be silane, titanate, zioconate, or a combination thereof. For example, the silane may include amino group, epoxy group, acrylic acid group, vinyl group, or a combination thereof. In a further embodiment, the coupling agent can first be mixed with (d) magnetic filler to add (e.g. graft) the coupling agent onto the surface of (d) magnetic filler. As such, the compatibility between (d) magnetic filler and the other organic materials in the resin composition can be improved further.

In one embodiment, (a) crosslinkable monomer with a biphenyl group has terminal alkylene groups and its chemical structure is shown in Formula 1,

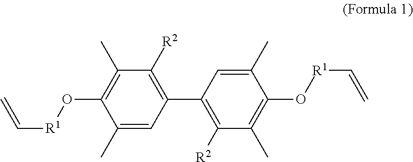

In Formula 1, R¹ is —CH₂—, —C(═O)—, or —(CH₂)—(C₆H₄)—, and R² is H or CH₃. For example, (a) crosslinkable monomer with a biphenyl group may have the chemical structure shown in Formula 2, 3, or 4.

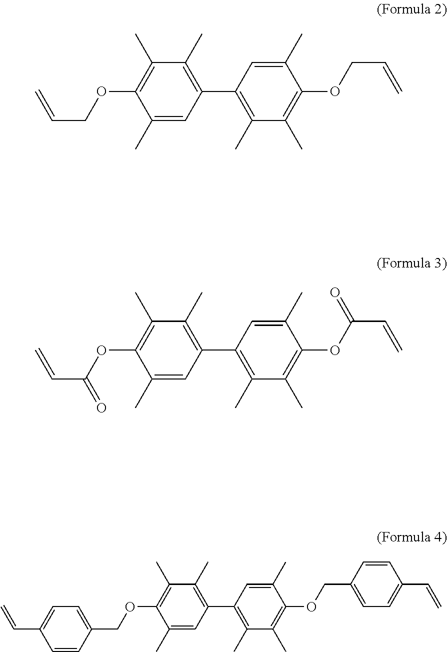

In this embodiment, (b) polyphenylene oxide also has terminal alkene groups, and its chemical structure is shown in Formula 5.

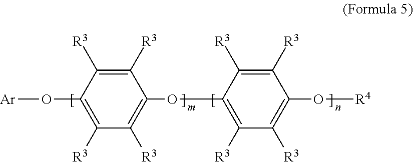

In Formula 5, Ar is aromatic group. Each of R³ is independently of H, CH₃,

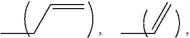

### R⁴ is

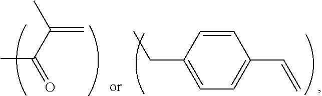

m and n are positive integers, and m+n=6˜300. In one embodiment, (b) polyphenylene oxide has a weight average molecular weight of 1000 to 7000. (b) Polyphenylene oxide having a weight average molecular weight that is too high may result in the substrate including the cured resin composition having poor mechanical properties due to poor solubility and too few reactive groups in the resin. (b) Polyphenylene oxide having a weight average molecular weight that is too low may result in a brittle substrate including the cured resin composition.

When (a) crosslinkable monomer with a biphenyl group has terminal alkene groups and (b) polyphenylene oxide has terminal alkene groups, (c) hardener includes triallyl isocyanurate (TAIC), trivinyl amine, triallyl cyanurate (TAC), or a combination thereof. In this embodiment, the resin composition further includes 0.001 to 0.05 parts by weight of (e) radical initiator (on the basis of 1.0 part by weight of (a) crosslinkable monomer with a biphenyl group). A ratio of (e) radical initiator that is too high may result in the molecular weight of the crosslinked resin composition being too low, such that the physical properties of the substrate are poor. A ratio of (e) radical initiator that is too low may result in an insufficient curing degree of the substrate, such that the processability of substrate is not good. For example, (e) radical initiator can be photo initiator, thermal initiator, or a combination thereof.

In one embodiment, (a) crosslinkable monomer with a biphenyl group has terminal epoxy groups, and its chemical structure is shown in Formula 6.

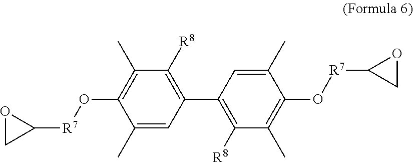

In Formula 6, R⁷ is —(CH₂)ₙ— and n=1-3. R⁸ is H or CH₃. In this embodiment, (b) polyphenylene oxide may have terminal hydroxyl groups, and its chemical structure is shown in Formula 7.

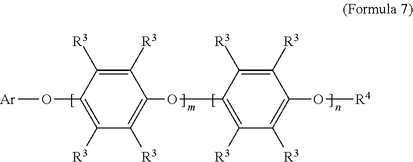

In Formula 7, Ar is aromatic group, each of R³ is independently of H, CH₃,

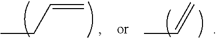

### R⁴ is

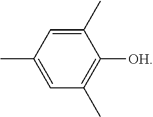

m and n are positive integers, and m+n=6˜300. (b) Polyphenylene oxide having a weight average molecular weight that is too high may result in poor mechanical properties of the substrate including the cured resin composition due to the poor solubility and too few reactive groups of the resin. (b) Polyphenylene oxide having a weight average molecular weight that is too low may result in a brittle substrate including the cured resin composition.

When (a) crosslinkable monomer with a biphenyl group has terminal epoxy groups and (b) polyphenylene oxide has terminal hydroxyl groups, (c) hardener includes active ester, multi-amine compound, multi-alcohol compound, or a combination thereof. For example, the active ester can be 8000-65T, 8150-60T, or 8100-65T commercially available from DIC. The multi-amine compound includes at least two amino groups, and multi-alcohol compound includes at least two hydroxyl groups. For example, the multi-amine compound can be 4,4′-diamino diphenyl sulfone (DDS), JER-113, or 4,4′-methylenedianiline (DDM). The multi-alcohol compound can be ethylene glycol, propylene glycol, or poly(ethylene glycol).

In one embodiment, (a) crosslinkable monomer with a biphenyl group has terminal epoxy groups, and its chemical structure is shown in Formula 6. (b) polyphenylene oxide has terminal alkene groups, and its chemical structure is shown in Formula 5. Therefore, the resin composition should include 1.0 to 10.0 parts by weight of (f) compatibilizer, and its chemical structure is shown in Formula 8.

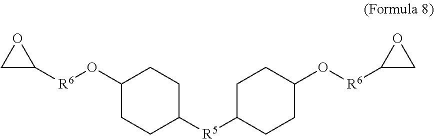

In Formula 8, R⁵ is —CH2- or —C(CH₃)₂—, R⁶ is —(CH₂)ₙ— and n is 1 to 3. A ratio of (f) compatibilizer that is too high results in a poor thermal conductivity of the cured resin composition or the substrate including the cured resin composition. A ratio of (f) compatibilizer that is too low results in the phase separation between (a) crosslinkable monomer with a biphenyl group and (b) polyphenylene oxide due to their incompatibility. In this embodiment. (c) hardener is DIC 8000-65T (active ester), amine, or phenol hardener for SA90 system (polyphenylene oxide having terminal hydroxyl groups). (c) Hardener can be common radical initiator (e.g. radical initiator) for SA9000 system (polyphenylene oxide having terminal alkene groups).

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Synthesis Example 1

40 g of 4,4′-bi(2,3,6-trimethylphenol) (TMP-BP, commercially available from Mitsubishi Chemical) and 33.9 g of allyl chloride (commercially available from Echo Chemical Co., Ltd.) were added to 40 g of dimethylsulfoxide (DMSO, commercially available from Echo Chemical Co., Ltd.). Small amounts of tetra-n-butyl ammonium (commercially available from Echo Chemical Co., Ltd.) and sodium hydroxide were added to the above mixture, and the mixture was heated to 80° C. to react for 3 hours. After the reaction was completed, the reaction was cooled to room temperature, filtered, and purified to obtain a product. The chemical structure of the product is shown below.

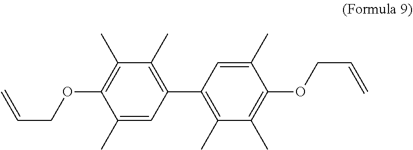 [SMILES: C=CCOc1c(C)cc(-c2cc(C)c(OCC=C)c(C)c2C)c(C)c1C]

The hydrogen spectrum of the product is shown below: ¹H NMR (500 MHz, CDCl₃): 56.69 (s, 2H), 6.12˜6.04 (m, 2H), 5.39 (d, J=17.5 Hz, 2H), 5.20 (d, J=10.5 Hz, 2H), 4.25 (d, J=5.5 Hz, 4H), 2.18 (s, 6H), 2.16 (s, 6H), 1.83 (s, 6H).

### Synthesis Example 2

40 g of TMP-BP and 40.22 g of acryloyl chloride (commercially available from Echo Chemical Co., Ltd.) were added to 100 g of tetrahydrofuran (THF). Small amounts of triethylamine (commercially available from Echo Chemical Co., Ltd.) and sodium hydroxide were added to the above mixture. The mixture was cooled to −30° C. to react, and then continuously stirred to room temperature. After the reaction was completed, the reaction was filtered, and purified to obtain a product. The chemical structure of the product is shown below.

### Formula 10

The hydrogen spectrum of the product is shown below: ¹H NMR (500 MHz, CDCl₃): 56.85 (s, 2H), 6.66 (d, J=17.5 Hz, 2H), 6.40 (dd, J=17.5 Hz, J=10.5 Hz, 2H), 6.05 (d, J=10.5 Hz, 2H), 2.12 (s, 6H), 2.10 (s, 6H), 1.94 (s, 6H).

### Synthesis Example 3

40 g of TMP-BP and 67.83 g of 4-vinylbenzyl chloride (commercially available from Echo Chemical Co., Ltd.) were added to 200 g of methyl ethyl ketone (MEK). Small amounts of tetra-n-butylammonium and potassium carbonate were added to the above mixture, and the mixture was heated to 90° C. to react for about 4 hours. After the reaction was completed, the reaction was cooled to room temperature, filtered, and purified to obtain a product. The chemical structure of the product is shown below.

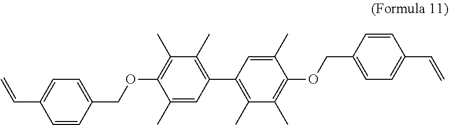 [SMILES: C=Cc1ccc(COc2c(C)cc(-c3cc(C)c(OCc4ccc(C=C)cc4)c(C)c3C)c(C)c2C)cc1]

The hydrogen spectrum of the product is shown below: ¹H NMR (500 MHz. CDCl₃): δ7.49-7.45 (m, 8H), 6.81 (s, 2H), 6.75 (dd, J=17.5 Hz, J=17.5 Hz, 2H), 5.78 (d, J=17.5 Hz, 2H), 5.27 (d, J=11 Hz, 2H), 4.83 (s, 4H), 2.30 (s, 6H), 2.28 (s, 6H), 1.94 (s, 6H).

### Synthesis Example 4

According to Example 24 in Taiwan Patent No. 1588251, magnetic filler was prepared, which was composed of a boron nitride powder having a surface partially coated with iron-containing oxide.

### Synthesis Example 5

10 g of the magnetic filler prepared in Synthesis Example 4 and 0.05 g of silane Z6011 (commercially available from Dow Corning) were added to 250 mL of water to be mixed, thereby obtaining a magnetic filler containing silane.

### Example 1-1

30.05 g of polyphenylene oxide with terminal alkylene groups SA9000 (commercially available from Sabic, having the chemical structure in Formula 5, in which m+n=6˜300, 1.0 parts by weight), 12.91 g of triallyl isocyanurate (TAIC) serving as a hardener (0.43 parts by weight), 4.53 g of poly(styrene-butadiene-styrene) (0.15 parts by weight), 0.64 g of radical initiator Perbutyl-P (commercially available from NOF Corporation, 0.021 parts by weight), 32.2 g of the magnetic filler in Synthesis Example 4 (1.07 parts by weight), and 4.23 g of silica FB-5 SDC (commercially available from Denka, 0.14 parts by weight) were added to 50 mL of co-solvent (toluene/xylene/cyclohexanone) and evenly mixed to form a resin composition.

The resin coating 13 could be prepared by following steps. The resin composition was coated onto a carrier, and the resin composition was magnetically aligned and dried to form the resin coating 13. The resin composition and the resin coating 13 therefrom were free of any glass fiber cloth. For example, the resin composition was coated onto a carrier 11 as shown in FIG. 1, and then magnetically aligned by an external magnetic field of 0.8 Tesla to magnetically align the magnetic filler in the resin composition, in which the external magnetic field is perpendicular to the surface direction of the carrier 11. In one embodiment, the magnetic alignment period was 600 seconds. The magnetically aligned resin composition and the carrier 11 were put into an oven at 160° C. to dry the resin composition for forming the resin coating 13 (B-stage). The multi-layered structure 100 was completed, which included the resin coating 13 on the carrier 11. The multi-layered structure 100 was put into the oven to be heated at 190° C. for 2 hours and then heated at 230° C. for 3 hours, thereby further curing the resin composition.

The resin coating of the multi-layered structure had had a thickness of 110 μm, a thermal conductivity of 1.31 W/mK (measured using the standard ASTM-D5470), a dielectric constant of 2.88 @ 10 GHz and a dielectric loss at 0.0036 @ 10 GHz (measured using the standard JIS C2565).

### Example 1-2

Repeated Example 1-1 to form the multi-layered structures 100. The two same multi-layered structures 100 were laminated to each other to form a substrate 200 (copper clad laminate), as shown in FIG. 2. The lamination was performed at a pressure of about 20 kg at 190° C. for 1 hour and then 230° C. for 2 hours. During the lamination, the resin coatings 13 of the two multi-layered structures 100 directly contacted to each other. The substrate 200 of the multi-layered structures had a thickness of about 220 μm, a thermal conductivity of 1.16 W/mK (measured using the standard ASTM-D5470), a dielectric constant of 2.98 @ 10 GHz and a dielectric loss at 0.0043 @ 10 GHz (measured using the standard JIS C2565).

### Example 2-1

6.45 g of thermally conductive resin with a biphenyl group YX4000 (commercially available from Mitsubishi Chemical, having the chemical structure in Formula 6, in which R⁷ is —CH₂— and R⁸ is H, 1.0 part by weight), 30.04 g of polyphenylene oxide having terminal alkene groups SA9000 (commercially available from Sabic, having the chemical structure in Formula 5, in which m+n=6˜300, 4.66 parts by weight), 6.45 g of hydrogenated epoxy resin monomer YX8000 serving as a compatibilizer (commercially available from Mitsubishi Chemical, having the chemical structure in Formula 8, in which R⁵ is —C(CH₃)₂— and R⁶ is —CH₂—, 1.0 part by weight), 3.16 g of multi-amine compound JER-113 serving as a hardener (commercially available from Mitsubishi Chemical, 0.49 parts by weight), 12.92 g of TAIC serving as a hardener (2.0 parts by weight), 4.52 g of poly(styrene-butadiene-styrene) (0.70 parts by weight), 0.59 g of radical initiator Perbutyl-P (commercially available from NFO Cooperation, 0.092 parts by weight), 39.27 g of the magnetic filler containing silane in Synthesis Example 5 (6.09 parts by weight), and 5.47 g of silica FB-5 SDC (commercially available from Denka, 0.85 parts by weight) were added to 50.0 mL of co-solvent (toluene/xylene/cyclohexanone) and evenly mixed to form a resin composition. The chemical structure of the multi-amine compound JER-113 is shown in Formula 12.

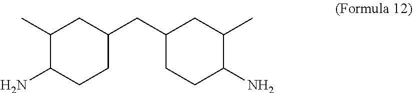 [SMILES: CC1CC(CC2CCC(N)C(C)C2)CCC1N]

The steps of forming the multi-layered structure 100 and the substrate 200 (copper clad laminate) were similar to those in Example 1-2, and the related descriptions are not repeated. The substrate 200 of the multi-layered structure had a thickness of about 2501 μm, a thermal conductivity of 1.49 W/mK, a dielectric constant of 2.99 @ 10 GHz and a dielectric loss at 0.0147 @ 10 GHz (measured using the standard JIS C2565).

### Example 2-2

6.45 g of thermally conductive resin with a biphenyl group YX4000 (commercially available from Mitsubishi Chemical, having the chemical structure in Formula 6, in which R⁷ is —CH₂— and R⁸ is H, 1.0 part by weight), 30.04 g of polyphenylene oxide having terminal alkene groups SA9000 (commercially available from Sabic, having the chemical structure in Formula 5, in which m+n=6˜300, 4.66 parts by weight), 6.45 g of hydrogenated epoxy resin monomer YX8000 serving as a compatibilizer (commercially available from Mitsubishi Chemical, having the chemical structure in Formula 8, in which R⁵ is —C(CH₃)₂— and R⁶ is —CH₂—, 1.0 part by weight), 3.16 g of multi-amine compound JER-113 serving as a hardener (commercially available from Mitsubishi Chemical, 0.49 parts by weight), 12.92 g of TAIC serving as a hardener (2.0 parts by weight), 4.52 g of poly(styrene-butadiene-styrene) (0.70 parts by weight), 0.59 g of radical initiator Perbutyl-P (commercially available from NFO Cooperation, 0.092 parts by weight), 14.14 g of the magnetic filler containing silane in Synthesis Example 5 (2.19 parts by weight), and 1.95 g of silica FB-5SDC (commercially available from Denka, 0.30 parts by weight) were added to 50.0 mL of co-solvent (toluene/xylene/cyclohexanone) and evenly mixed to form a resin composition.

Glass fiber cloth #1027 (commercially available from ASCO, Japan) was impregnated into the resin composition (A-stage), and the weight of the resin composition and the total weight of the resin composition and the glass fiber cloth had a ratio of 73%. The glass fiber cloth was then put into an oven at 160.0° C. to dry the resin composition to form a prepreg 31 (B-stage). The prepreg had a thickness of 0.05 mm. One prepreg 31 was disposed between the two multi-layered structure 100 in Example 2-1, and then laminated to form a substrate 300 (copper clad laminate), as shown in FIG. 3. The lamination was performed at a pressure of about 20 kg at 190′C for 1.5 hours and then 230′C for 2 hours. During the lamination, the resin coatings 13 of the two multi-layered structures 100 contacted the prepreg 31.

The substrate 300 of the multi-layered structure had a thickness of about 260 μm, a thermal conductivity of 0.93 W/mK, a dielectric constant of 3.08 @ 10 GHz and a dielectric loss at 0.0123 @ 10 GHz (measured using the standard JIS C2565).

### Example 3

20 g of polyphenylene oxide having terminal alkene groups MGC1200 (commercially available from Mitsubishi, having the chemical structure in Formula 5, in which m+n=6-300, 1.0 parts by weight), 8 g of TAIC serving as a hardener (0.4 parts by weight), 6 g of poly(styrene-butadiene-styrene) (0.3 parts by weight), 0.476 g of radical initiator Perbutyl-P (commercially available from NFO Cooperation, 0.024 parts by weight), and 16.3 g of the magnetic filler in Synthesis Example 4 (0.82 parts by weight) were added to 50.0 mL of co-solvent (toluene/xylene/cyclohexanone) and evenly mixed to form a resin composition.

The steps of forming the multi-layered structure 100 and the substrate 200 (copper clad laminate) were similar to those in Example 1-2, and the related descriptions are not repeated, in which the magnetic alignment period was 3 seconds. The substrate 200 of the multi-layered structure had a thickness of about 115 μm, a thermal conductivity of 1.26 W/mK, a dielectric constant of 2.82 @ 10 GHz and a dielectric loss at 0.0048 @ 10 GHz (measured using the standard JIS C2565).

### Example 4

9712.46 g of polyphenylene oxide having terminal alkene groups MGC1200 (commercially available from Mitsubishi, having the chemical structure in Formula 5, in which m+n=6-300, 1.0 parts by weight), 3885 g of TAIC serving as a hardener (0.4 parts by weight), 1457.11 g of poly(styrene-butadiene-styrene) (0.15 parts by weight), 188.82 g of radical initiator Perbutyl-P (commercially available from NFO Cooperation, 0.019 parts by weight), 4690.92 g of the magnetic filler in Synthesis Example 4 (0.48 parts by weight), 3518.42 g of silica FB-5SDC (commercially available from Denka, 0.36 parts by weight), and 38.68 g of silane coupling agent (commercially available from Dow Corning, 0.004 parts by weight) were added to 13278 mL of co-solvent (toluene/xylene/cyclohexanone) and evenly mixed to form a resin composition.

Glass fiber cloth #1037 (commercially available from ASCO, Japan) was impregnated into the resin composition (A-stage), and the weight of the resin composition and the total weight of the resin composition and the glass fiber cloth had a ratio of 81%. The glass fiber cloth was then magnetically aligned by an external magnetic field of 0.8 Tesla to magnetically align the magnetic filler in the resin composition, in which the external magnetic field is perpendicular to the surface direction of the glass fiber cloth. The magnetic alignment period was 3 seconds. The glass fiber cloth was then put into an oven at 160.0° C. to dry the resin composition to form a prepreg 31 (B-stage). The prepreg had a thickness of 0.075 mm. One prepreg 31 was disposed between the two multi-layered structure 100 in Example 3, and then laminated to form a substrate 300 (copper clad laminate), as shown in FIG. 3. The lamination was performed at a pressure of about 20 kg at 190′C for 1.5 hours and then 230° C. for 2 hours. During the lamination, the resin coatings 13 of the two multi-layered structures 100 contacted the prepreg 31.

The substrate 300 of the multi-layered structure had a thickness of about 250 μm, a thermal conductivity of 0.96 W/mK, a dielectric constant of 3.01 @ 10 GHz and a dielectric loss at 0.0053 @ 10 GHz (measured using the standard JIS C2565).

### Comparative Example 1

The resin composition was similar to that in Example 4. Glass fiber cloth #1037 (commercially available from ASCO. Japan) was impregnated into the resin composition (A-stage), and the weight of the resin composition and the total weight of the resin composition and the glass fiber cloth had a ratio of 81%. The glass fiber cloth (without the magnetic alignment) was then put into an oven at 160.0° C. to dry the resin composition to form a prepreg 31 (B-stage). The prepreg had a thickness of 0.075 mm. One prepreg 31 (without the magnetic alignment) was disposed between the two multi-layered structure 100 in Example 3, and then laminated to form a substrate 300 (copper clad laminate), as shown in FIG. 3. The lamination was performed at a pressure of about 20 kg at 190° C. for 1.5 hours and then 230° C. for 2 hours. During the lamination, the resin coatings 13 of the two multi-layered structures 100 contacted the prepreg 31.

The substrate 300 of the multi-layered structure had a thickness of about 2501 μm, a thermal conductivity of 0.82 W/mK, a dielectric constant of 2.99 @ 10 GHz and a dielectric loss at 0.0049 @ 10 GHz (measured using the standard JIS C2565).

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A multi-layered structure, comprising:
a carrier; and
a resin coating on the carrier,
wherein the resin coating is formed by magnetically aligning and drying a resin composition, and the resin composition comprises:
1.0 part by weight of (a) crosslinkable monomer with a biphenyl group;
1.0 to 20.0 parts by weight of (b) polyphenylene oxide;
0.1 to 10.0 parts by weight of (c) hardener; and
0.1 to 80.0 parts by weight of (d) magnetic filler,
wherein (d) magnetic filler is boron nitride, aluminum nitride, silicon nitride, silicon carbide, aluminum oxide, carbon nitride, octahedral carbon, or a combination thereof, with a surface modified by iron-containing oxide, and (d) magnetic filler is sheet-shaped or needle-shaped.

2. The multi-layered structure as claimed in claim 1, wherein the resin coating is free of glass fiber cloth.

3. The multi-layered structure as claimed in claim 1, wherein (a) crosslinkable monomer with a biphenyl group has terminal alkylene groups, which has a chemical structure of: 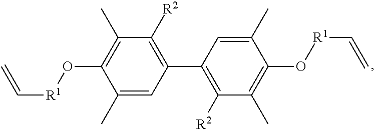
wherein R¹ is —CH₂—, —C(═O)—, or —(CH₂)—(C₆H₄)—; and
R² is H or CH₃.

4. The multi-layered structure as claimed in claim 3, wherein (b) polyphenylene oxide has terminal alkylene groups, which has a chemical structure of: 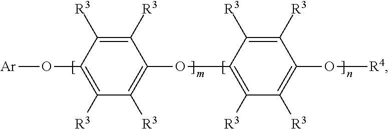
wherein Ar is aromatic group,
each of R³ is independently of H, CH₃, 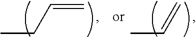
R⁴ is 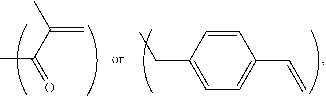
m and n are positive integers, and
m+n=6˜300.

5. The multi-layered structure as claimed in claim 3, wherein (c) hardener comprises triallyl isocyanurate, trivinyl amine, triallyl cyanurate, or a combination thereof.

6. The multi-layered structure as claimed in claim 3, wherein the resin composition further comprises 0.001 to 0.05 parts by weight of (e) radical initiator.

7. The multi-layered structure as claimed in claim 1, wherein (a) crosslinkable monomer with a biphenyl group has terminal epoxy groups, which has a chemical structure of: 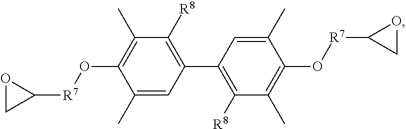
wherein R⁷ is —(CH₂)ₙ—, and n=1˜3, and
R⁸ is H or CH₃.

8. The multi-layered structure as claimed in claim 1, wherein (b) polyphenylene oxide has terminal hydroxyl groups, which has a chemical structure of: 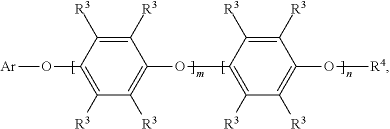
wherein Ar is aromatic group,
each of R³ is independently of H, CH₃, 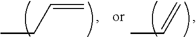
R⁴ is 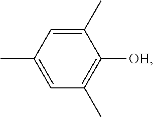
m and n are positive integers, and
m+n=6˜300.

9. The multi-layered structure as claimed in claim 7, wherein (c) hardener comprises active ester, multi-amine compound, multi-alcohol compound, or a combination thereof.

10. The multi-layered structure as claimed in claim 7, wherein the resin composition further comprises 1.0 to 10.0 parts by weight of (f) compatibilizer, which has a chemical structure of: 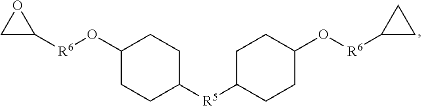
wherein R⁵ is —CH₂— or —C(CH₃)₂—; and
R⁶ is —(CH₂)ₙ—, and n=1˜3,
wherein (b) polyphenylene oxide has terminal alkylene groups, which has a chemical structure of: 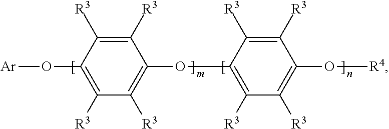
wherein Ar is aromatic group,
each of R³ is independently of H, CH₃, 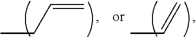
R⁴ is 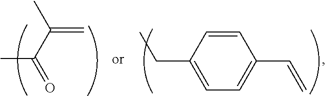
m and n are positive integers, and
m+n=6˜300.

11. The multi-layered structure as claimed in claim 10, wherein (c) hardener includes (c1) triallyl isocyanurate, trivinyl amine, triallyl cyanurate, or a combination thereof and (c2) active ester, multi-amine compound, multi-alcohol compound, or a combination thereof.

12. The multi-layered structure as claimed in claim 10, wherein the resin composition further comprising 0.001 to 0.05 parts by weight of (e) radical initiator.

13. The multi-layered structure as claimed in claim 1, wherein the resin composition further comprising 0.01% to 10.0% parts by weight of coupling agent.

14. The multi-layered structure as claimed in claim 13, wherein the coupling agent is added onto the surface of (d) magnetic tiller.

15. A substrate, comprising:
the two multi-layered structures as claimed in claim 1 laminated to each other.

16. The substrate as claimed in claim 15, having a thickness of 50 μm to 500 μm.

17. The substrate as claimed in claim 15, further comprising a prepreg disposed between the two multi-layered structures and laminated with the two multi-layered structures,
wherein the prepreg is formed by impregnating a reinforcing material into another resin composition, and then by magnetically aligning and drying the other resin composition,
wherein the other resin composition comprises:
1.0 part by weight of (a) crosslinkable monomer with a biphenyl group;
1.0 to 20.0 parts by weight of (b) polyphenylene oxide;
0.1 to 10.0 parts by weight of (c) hardener; and
0.1 to 80.0 parts by weight of (d) magnetic filler.

18. The substrate as claimed in claim 17, wherein the reinforcing material comprises glass, ceramic, carbon material, resin, or a combination thereof, and the reinforcing material has a shape of fiber, powder, sheet, texture, or a combination thereof.
